(19) United States
(12) Patent Application Publication
(10) Pub. No.: US 2025/0279300 A1
(43) Pub. Date: Sep. 4, 2025

(54) SEMICONDUCTOR PRODUCTION APPARATUS SYSTEM

(71) Applicant: KAWASAKI JUKOGYO KABUSHIKI KAISHA, Kobe-shi, Hyogo (JP)

(72) Inventors: Satoshi HASHIZAKI, Kobe-shi (JP); Shinya KITANO, Kobe-shi (JP); Ryousuke KANAMARU, Kobe-shi (JP); Katsuhiro YAMASHITA, Kobe-shi (JP); Tomoya NAGASAWA, Kobe-shi (JP)

(73) Assignee: KAWASAKI JUKOGYO KABUSHIKI KAISHA, Kobe-shi, Hyogo (JP)

(21) Appl. No.: 18/859,319

(22) PCT Filed: Apr. 24, 2023
(86) PCT No.: PCT/JP2023/016057

§ 371 Date: Oct. 23, 2024

(30) Foreign Application Priority Data
Apr. 27, 2022 (JP) 2022-073797

(51) Int. Cl. H01L 21/67; H01L 21/677

(52) U.S. Cl. CPC H01L 21/67259; H01L 21/67742; H01L 21/67754; H01L 21/67757

(57) ABSTRACT

A semiconductor production apparatus system includes a substrate-holding hand including a first blade support and a second blade support. The semiconductor production apparatus system includes an image capturer for capturing an image of an inspection target including at least one of substrates, a component of a semiconductor production apparatus and the substrate-holding hand, and a controller for detecting a state of the inspection target based on the captured image captured by the image capturer. The image capturer is arranged in the second blade support.

### TECHNICAL FIELD

The present disclosure relates to a semiconductor production apparatus system, and in particular to a semiconductor production apparatus system including a substrate-holding hands.

### BACKGROUND ART

Substrate conveyor robots including hands for holding substrates are known in the art. See Japanese Patent Publication No. JP 5303301, for example.

The above Japanese Patent Publication No. JP 5303301 discloses a robot for conveying substrates in and out. The robot includes a substrate-placing mechanism, a sensing hand, a first arm, and a second arm. The substrate-placing mechanism includes a plurality of hand forks on which substrates are placed. The substrate-placing mechanism is supported by the first arm. Also, the sensing hand includes an optical sensor including a light emitter and a light receiver on its distal end. The sensing hand detects storage states of the substrates. In addition to detecting the storage states, the sensing hand conveys the substrates out. Also, the sensing hand is supported by the second arm.

### PRIOR ART

### Patent Document

Patent Document 1: Japanese Patent Publication No. JP 5303301

### SUMMARY OF THE INVENTION

However, since the robot described in the above Japanese Patent Publication No. JP 5303301 detects the storage states of substrates by using the optical sensor including the light emitter and the light receiver, it is considered difficult to detect a state of a part of each substrate that is not included in a detection area of the sensor. Although not stated in the above Japanese Patent Publication No. JP 5303301, in a semiconductor production apparatus for performing at least one of conveyance of a substrate, application of processing to a substrate and storing a substrate, states of components of the semiconductor production apparatus including a deterioration state of a storage of the semiconductor production apparatus or a consumption of a consumable are required to be confirmed in some cases. Since the optical sensor for detecting a placement state of a substrate in the above Japanese Patent Publication No. JP 5303301 does not include light emitters and light receivers that are arranged corresponding to the components of the semiconductor production apparatus, it is considered difficult to detect the states of the components of the semiconductor production apparatus in such a case. Also, although not stated in the above Japanese Patent Publication No. JP 5303301, a state of a substrate-holding hand for conveying a substrate is required to be confirmed in some cases. In such a case, it is difficult for the optical sensor for detecting the placement state of the substrate in the above Japanese Patent Publication No. JP 5303301 to detect a state, such as misalignment, of the substrate-holding hand itself on which the sensor is arranged. For these reasons, it is desired to easily detect a state of an inspection target including at least one of a substrate, a component of a semiconductor production apparatus and a substrate-holding hand.

The present disclosure is intended to solve the above problems, and one object of the present disclosure is to provide a semiconductor production apparatus system capable of easily detecting a state of an inspection target including at least one of a substrate, a component of a semiconductor production apparatus and a substrate-holding hand.

A semiconductor production apparatus system according to one aspect of the present disclosure is a semiconductor production apparatus system for at least one of conveyance of substrates into and out of a semiconductor production apparatus for performing at least one of conveyance of the substrates, application of processing to the substrates and storing the substrates, the semiconductor production apparatus system comprising a substrate-holding hand including a first blade support for supporting a proximal end of a first blade on which one of the substrates is placed, and a second blade support for operating independently of the first blade support and for supporting a proximal end of a second blade on which another of the substrates is placed; an image capturer for capturing an image of an inspection target including at least one of the substrates, a component of the semiconductor production apparatus and the substrate-holding hand; and a controller for detecting a state of the inspection target based on the captured image captured by the image capturer, wherein the image capturer is arranged in the second blade support.

In the semiconductor production apparatus system according to the aspect of the present disclosure, as discussed above, an image capturer for capturing an image of an inspection target including at least one of the substrates, a component of the semiconductor production apparatus and the substrate-holding hand; and a controller for detecting a state of the inspection target based on the captured image captured by the image capturer are provided. Accordingly, since the inspection target can be captured by the image capturer, it is possible to capture an image of the state of the inspection target in a wider area as compared with a case in which an optical sensor is arranged in a distal end of a hand to detect storage states of substrates. For this reason, in a case in which the inspection target is substrates, states of the inspection target can be easily detected based on the captured image captured by the image capturer. Also, the state of the inspection target can be detected based on the captured image without light emitters and light receivers being are arranged corresponding to the inspection target by detecting the state of the inspection target based on the captured image captured by the image capturer. For this reason, in a case in which the inspection target is the component of the semiconductor production apparatus, it is possible to easily detect the state of the inspection target based on the captured image. Also, in a case in which the inspection target is the substrate-holding hand itself, it is possible to easily detect the state of the inspection target based on the captured image. Consequently, it is possible to easily detect the state of the inspection target including at least one of the substrate, the component of the semiconductor production apparatus and the substrate-holding hand.

According to the present disclosure, it is possible to easily detect a state of an inspection target including at least one of a substrate, a component of a semiconductor production apparatus and a substrate-holding hand.

### BRIEF DESCRIPTION OF THE DRAWINGS

FIG. 1 is a block diagram showing an entire configuration of a substrate processing system according to a first embodiment.

FIG. 2 is a schematic diagram showing configurations of a substrate-conveying robot, a storage enclosure, and a storage of a processor according to the first embodiment.

FIG. 3 is a perspective view illustrating a first blade support and a second blade support, which are moved together.

FIG. 4 is a perspective view illustrating the first blade support and the second blade support, which is moved independently of the first blade support.

FIG. 5 is a front view for illustrating an arrangement of an image capturer in the second blade support.

FIG. 6 is a side view for illustrating capture of an image of substrates with being stored in a storage.

FIG. 7 is a view showing an exemplary captured image of the substrates with being stored in the storage.

FIG. 8 is a side view for illustrating capture of an image of the storage with no substrate being stored.

FIG. 9 is a view showing an exemplary captured image of the storage with no substrate being stored.

FIG. 10 is a view illustrating an exemplary indication on a display if an anomaly is detected.

FIG. 11 is a flowchart illustrating a substrate-conveying method according to the first embodiment.

FIG. 12 is a flowchart illustrating an inspection-target anomaly detection method according to the first embodiment.

FIG. 13 is a block diagram showing an entire configuration of a substrate processing system according to a second embodiment.

FIG. 14 is a schematic view showing a configuration of a substrate-conveying robot according to the second embodiment.

FIG. 15 is a block diagram showing an entire configuration of a substrate processing system according to a third embodiment.

FIG. 16 is a front view for illustrating an arrangement of two image capturers.

### MODES FOR CARRYING OUT THE INVENTION

The following description will describe embodiments embodying the present disclosure with reference to the drawings.

### First Embodiment

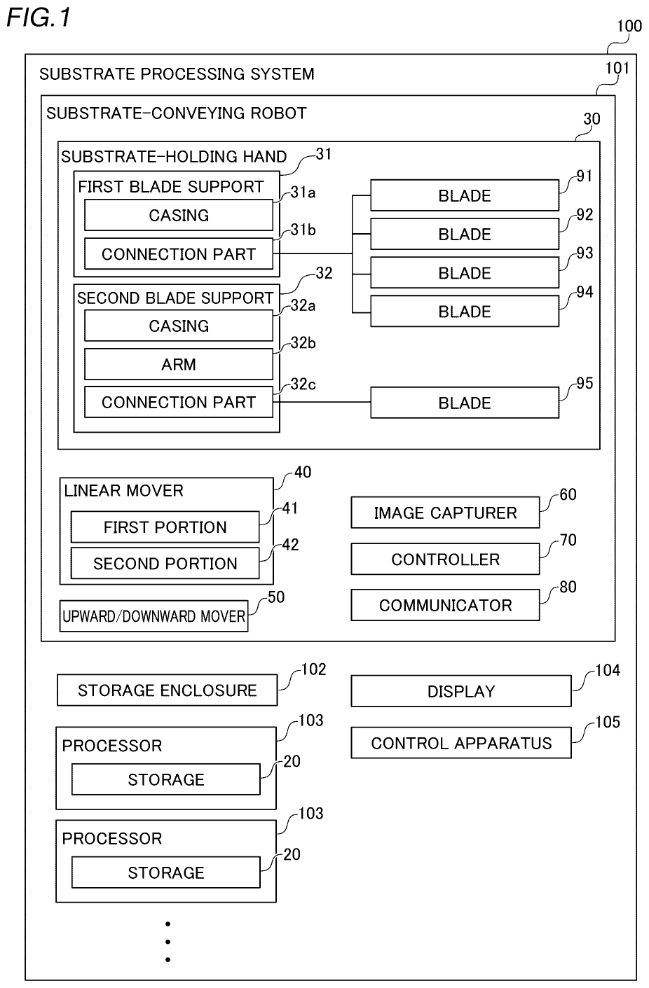

The following description describes a configuration of a substrate processing system 100 according to a first embodiment with reference to FIGS. 1 to 10. The substrate processing system 100 is an example of a semiconductor production apparatus system.

As shown in FIG. 1, the substrate processing system 100 includes a substrate-conveying robot 101, a storage enclosure 102, a plurality of processors 103, a display 104, and a control apparatus 105. The substrate processing system 100 applies processing to a substrate 10, such as a semiconductor wafer or printed circuit board, for example. The substrate processing system 100 processes a plurality of substrates 10 stored in the storage enclosure 102. The storage enclosure 102 may also store the substrates 10 to which processing has been applied. The substrate 10 has a roughly disk shape, for example, and is arranged adjacent to each other in a vertical direction and stored in the storage enclosure 102. The processor 103 applies processing, such as resist coating or etching, to the substrates 10, for example. The storage enclosure 102 is an example of a semiconductor production apparatus and an example of a storage. The processor 103 is an example of the semiconductor production apparatus.

The display 104 indicates information on a status of the substrate processing system 100. Specifically, the display 104 indicates information indicating operating statuses of the plurality of processors 103 and an operating status of the substrate-conveying robot 101. The display 104 includes, for example, a liquid crystal display. The control apparatus 105 is a higher-level controller that controls the entire substrate processing system 100. The control apparatus 105 outputs signals for operating the plurality of processors 103 and the substrate-conveying robot 101. The control apparatus 105 is a computer including a CPU (Central Processing Unit), a RAM (Random Access Memory), a ROM (Read Only Memory), and the like.

The substrate-conveying robot 101 is a robot for conveying the substrate 10. The substrate-conveying robot 101 performs at least one of conveying the substrates 10 out of the processors 103 that apply processing to the substrates 10 and conveying the substrates 10 into the processors 103. The substrate-conveying robot 101 performs at least one of conveying the substrates 10 out of the storage enclosure 102 for storing the substrates 10 and conveying the substrates 10 into the storage enclosure 102. The processors 103 includes storages 20 for storing a plurality of substrates 10. For example, the substrate-conveying robot 101 conveys the substrates 10 that are stored in the storage enclosure 102 to the storage 20 in one of the plurality of processors 103. Subsequently, the substrate-conveying robot 101 conveys the substrates 10 that have been processed in one of the processors 103 from the storage 20 in the one processor 103 to the storage 20 in another of the plurality of processors 103. Here, the storage 20 is an example of a component of the semiconductor production apparatus.

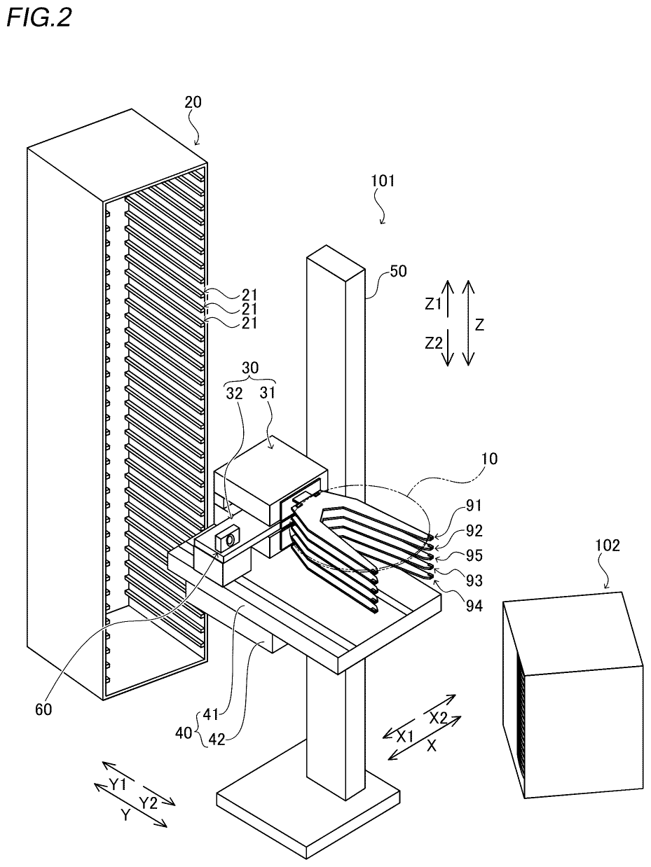

As shown in FIG. 2, the substrate-conveying robot 101 includes a substrate-holding hand 30, a linear mover 40, and an upward/downward mover 50.

Five blades, which are blades 91, 92, 93, 94 and 95, are arranged on the substrate-holding hand 30. One of the substrates 10 are placed on each of the blades 91, 92, 93, 94 and 95. Specifically, the blades 91, 92, 93, 94 and 95 are thin plate-shaped supports for supporting the substrates 10. The blades 91, 92, 93, 94 and 95 have bifurcated distal ends. Also, each of the blades 91, 92, 93, 94 and 95 supports a back surface of an outer edge of the substrate 10, which has the roughly disk shape, from a Z2-direction side, which is a lower side in the vertical direction. The substrates 10 are placed separately on the blades 91, 92, 93, 94 and 95 one by one. Here, the blades 91, 92, 93 and 94 are examples of first blades. Also, the blade 95 is an example of a second blade.

The substrate-holding hand 30 includes a first blade support 31 and a second blade support 32. The first blade support 31 supports proximal ends of a plurality of blades 91, 92, 93 and 94. That is, the first blade support 31 supports the proximal end of each of the plurality of blades 91, 92, 93 and 94 from a Y1-direction side in FIG. 2. Also, the second blade support 32 supports a proximal end of one blade 95 on which the substrate 10 is placed separately from the plurality of blades 91, 92, 93 and 94. In other words, the second blade support 32 supports the proximal end of the blade 95 from the Y1-direction side in FIG. 2. The second blade support 32 operates independently of the first blade support 31. In an arrangement of the five blades 91, 92, 93, 94 and 95 in the substrate-holding hand 30, the blade 91, the blade 92, the blade 95, the blade 93 and the blade 94 are arranged in this order in a Z direction, which is the vertical direction, from an upper side in the vertical direction.

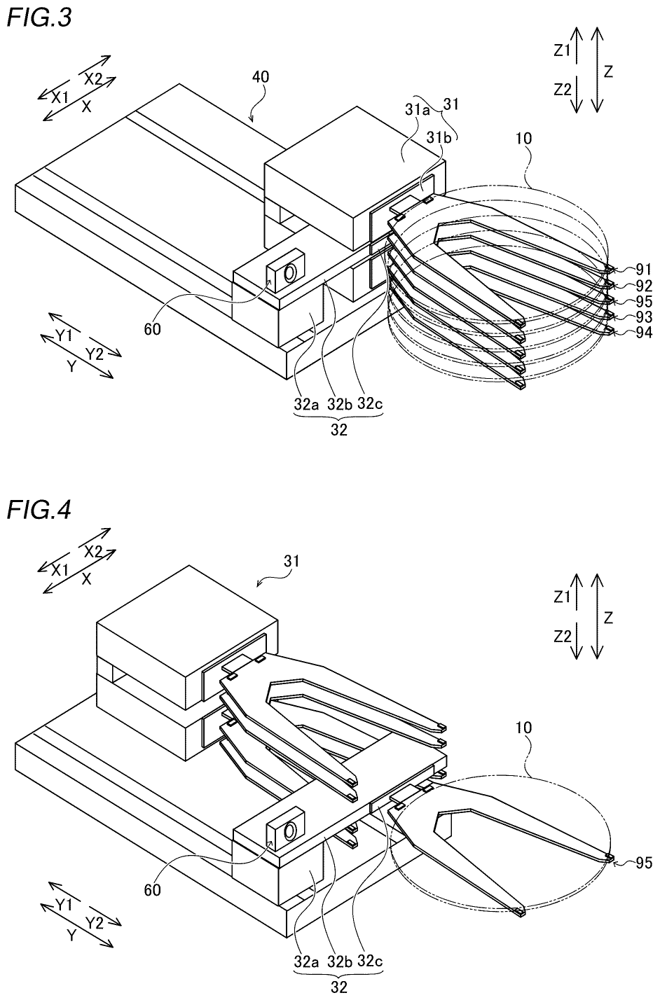

As shown in FIG. 3, the first blade support 31 in the substrate-holding hand 30 includes a casing 31a having a substantially rectangular parallelepiped shape. Also, the first blade support 31 includes connection parts 31b that are connected to the blades 91, 92, 93 and 94. The second blade support 32 includes a casing 32a, an arm 32b, and a connection part 32c. The casing 32a is arranged on an X1-direction side, which is a lateral side with respect to the first blade support 31, and has a substantially rectangular parallelepiped shape. The arm 32b is a flat plate-like part extending from the casing 32a toward the first blade support 31 in an X2 direction. The arm 32b extends toward the X2-direction side to be inserted into the casing 31a of the first blade support 31. The connection part 32c is a part in an end part of the arm 32b in the X2-direction side connected to the blade 95. That is, the arm 32b extends toward the X2-direction side so that the connection part 32c, to which blade 95 is connected, is arranged between connection parts 31b to which the blades 91 and 92 are connected, and the connection part 31b to which the blades 93 and 94 of the first blade support 31 are connected. The casing 31a of the first blade support 31 has a slit-like gap in its central part in the Z direction into which the arm 32b of the second blade support 32 is inserted. In other words, the casing 31a of the first blade support 31 has a shape that is obtained by dividing the casing into two parts, which are a part to which the blades 91 and 92 are connected and a part to which the blades 93 and 94 are connected, in the Z direction, which is the vertical direction. Also, Y1-direction sides of the two divided parts of the casing 31a are connected to each other. Also, the casing 32a of the second blade support 32 is connected to the linear mover 40, which will be described later. Here, the casing 31a in the first blade support 31 is connected to the linear mover 40. Also, the first blade support 31 changes positions of the blades 91, 92, 93 and 94 in the Z direction. Specifically, the first blade support 31 changes distances between the five blades 91, 92, 93, 94 and 95 from each other in the vertical direction with the blade 95 supported by the second blade support 32 being centered. In other words, the substrate-holding hand 30 changes the distances between the five blades 91, 92, 93, 94 and 95 from each other to agree with arrangement intervals in the vertical direction of the plurality of substrates 10 that are placed in the storage enclosure 102 or in the storage 20 of the processor 103.

As shown in FIG. 2, the linear mover 40 includes a first portion 41 and a second portion 42. The first blade support 31 and the second blade support 32 are connected to the first portion 41. The linear mover 40 linearly moves the substrate-holding hand 30. The linear mover 40 linearly moves the second blade support 32 independently of the first blade support 31. Specifically, the linear mover 40 slidably moves the first blade support 31 and the second blade support 32 in a straight line. The linear mover 40 moves the first blade support 31 and the second blade support 32 together with each other, and also moves the second blade support 32 without moving the first blade support 31. In other words, the first portion 41 of the linear mover 40 is connected to the casing 31a of the first blade support 31 and the casing 32a of the second blade support 32, and switches between an operation that moves the casing 31a and the casing 32a together with each other, and an operation that moves only the casing 32a.

Also, the linear mover 40 conveys the substrates 10 in or out by moving the substrate-holding hand 30 to the Y2-direction side from an arrangement in which the first blade support 31 and the second blade support 32 of the substrate-holding hand 30 are arranged on the Y1-direction side of the first portion 41. The state in which the first blade support 31 and the second blade support 32 are arranged on the Y1-direction side refers to an avoidance state. As shown in FIG. 3, when moving the five blades 91, 92, 93, 94 and 95, the linear mover 40 moves both the first blade support 31 and the second blade support 32 together with each other. As shown in FIG. 4, when moving only one blade 95, the linear mover 40 moves only the second blade support 32 to the Y2-direction side from an arrangement in which both the first blade support 31 and the second blade support 32 are arranged on the Y1-direction side. In other words, the substrate-holding hand 30 switches between conveyance of the five substrates 10 together and conveyance of only one substrate 10. Here, the Y1 and Y2 directions are examples of movement directions of the second blade.

The first portion 41 rotates about the Z direction as a rotation axis with respect to the second portion 42 in the linear mover 40. That is, the first portion 41 rotates in an XY plane. When the first portion 41 rotates, the substrate-holding hand 30 correspondingly rotates about the Z direction as the rotation axis. Here, when the first portion 41 is rotated, the first blade support 31 and the second blade support 32 of the substrate-holding hand 30 are positioned in the avoidance state. The linear mover 40 includes, for example, a servomotor as a drive mechanism. A driving force of the servomotor is used as power for moving the substrate-holding hand 30 through a belt-and-pulley transmission, a ball-and-screw transmission, or the like in the linear mover 40. The linear mover 40 includes an encoder for acquiring a rotational speed of the servomotor. Operations of the linear mover 40 are controlled by the controller 70.

As shown in FIG. 2, the upward/downward mover 50 moves the linear mover 40 upward/downward. The upward/downward mover 50 moves the substrate-holding hand 30 upward/downward by moving the linear mover 40 upward/downward. Specifically, the upward/downward mover 50 is arranged to extend in the Z direction, which is the vertical direction. The second portion 42 of the linear mover 40 is connected to the upward/downward mover 50. Accordingly, the linear mover 40 and the substrate-holding hand 30 are moved together with each other upward/downward by moving second portion 42 upward/downward by using the upward/downward mover 50. The upward/downward mover 50 includes, for example, a servomotor as a drive mechanism. A driving force of the servomotor is used as power for moving the substrate-holding hand upward/downward through a belt-and-pulley transmission, a ball-and-screw transmission, or the like in the upward/downward mover 50. The upward/downward mover 50 includes an encoder for acquiring a rotational speed of the servomotor. Similar to the linear mover 40, operations of the upward/downward mover 50 are controlled by the controller 70.

As shown in FIG. 5, in the first embodiment, an image capturer 60 is arranged in the second blade support 32. The image capturer 60 is arranged on the second blade support 32 with being spaced away from the connection part 32c between the second blade support 32 and the blade 95. In other words, the image capturer 60 is arranged on the second blade support 32 with being also spaced away from the first blade support 31, which supports the plurality of blades 91, 92, 93, 94 and 95. Specifically, the image capturer 60 is arranged in a part of the second blade support 32 on an outside with respect to an edge of the blade 95 in the X1 direction as viewed in the Y1 and Y2 directions, which are the movement directions of the blade 95 when the substrate 10 is conveyed in or out to be spaced away from the connection part 32c. The image capturer 60 is spaced away from the connection part 32c to prevent influences of heat generated in the image capturer 60 on operations of the connection part 32c and the first blade support 31. In more detail, the image capturer 60 is arranged above the casing 32a in the second blade support 32. The image capturer 60 is arranged above the casing 32a to capture an image on the Y2-direction side, which is a blade 95 movement direction side. Also, the image capturer 60 is arranged on a Z1-direction side, which is an upper side in the vertical direction, with respect to the blade 95. That is, the image capturer 60 is positioned above a placement surface on which the substrate 10 is placed in the blade 95. The image capturer 60 moves together with the second blade support 32. In other words, the image capturer 60 is moved together with the second blade support 32 by operation of the linear mover 40 and the upward/downward mover 50.

The image capturer 60 captures an image of the inspection target including at least one of the substrates 10, components of the storage enclosure 102 and the processor 103, and the substrate-holding hand 30 based on control by the controller 70. The captured image P captured by the image capturer 60 is output to the controller 70. The image capturer 60 includes a two-dimensional camera such as a CCD (Charge Coupled Device) image sensor or CMOS (Complementary Metal Oxide Semiconductor) image sensor, including a plurality of imaging elements, for example. The image capturer 60 may include a three-dimensional camera.

The controller 70 controls operations of the substrate-conveying robot 101. The controller 70 is, for example, a computer including a CPU, RAM, ROM, and the like. The controller 70 includes a storage device that includes a flash memory, such as an SSD (Solid State Drive). The controller 70 controls the operations of the parts of the substrate-conveying robot 101 based on programs and parameters previously stored in the storage device.

The communicator 80 communicates with the plurality of processors 103. The communicator 80 also communicates with the higher-level control apparatus 105. The communicator 80 includes a communication module for communication through LAN (Local Area Network) and the like. In other words, the controller 70 communicates with the outside of the substrate-conveying robot 101 through the communicator 80.

### Detection of State of Inspection Target

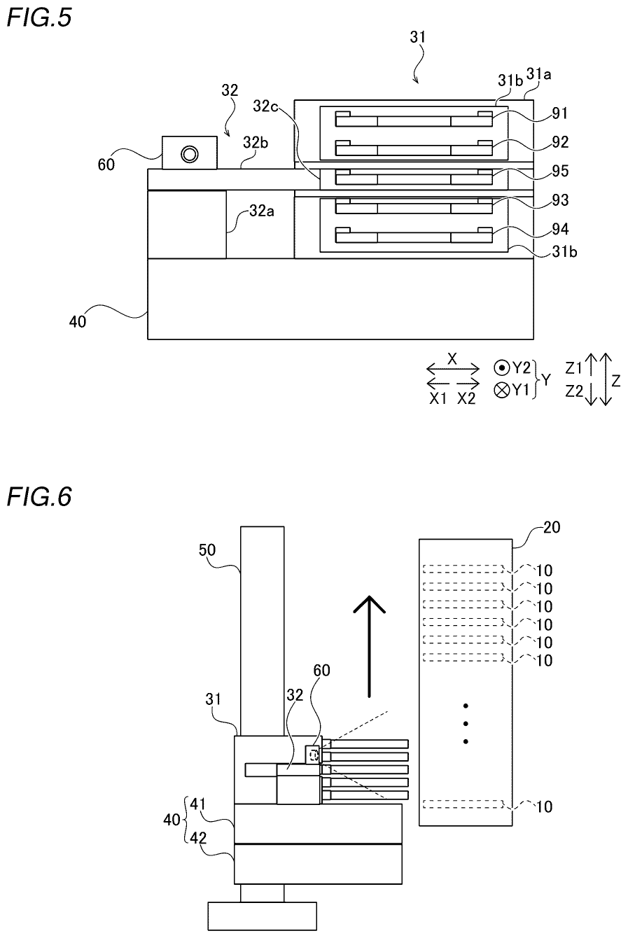

The following description describes detection of a state of the inspection target by using the controller 70 with reference to FIGS. 6 to 9.

In the first embodiment, the controller 70 detects the state of the inspection target based on the captured image P captured by the image capturer 60. The inspection target includes at least one of the substrates 10 that are placed in the storage 20 and the storage enclosure 102, the components of the storage enclosure 102 and the processor 103, and the substrate-holding hand 30. For example, the component of the storage enclosure 102 is a part of the storage enclosure 102 on which the substrate 10 is placed. The component of the processor 103 is equipment, such as the storage 20, and a consumable in the processor 103. In other words, the controller 70 performs detection of placement states of the substrates 10 in the storage 20 and the storage enclosure 102, detection of an anomaly or deterioration of the components in equipment forming the storage enclosure 102 and the processor 103, detection of an anomaly or deterioration of the substrate-holding hand 30, and detection of a consumption degree of a consumable in each part in the substrate processing system 100 including the processor 103 by applying image analysis processing to the captured image P captured by the image capturer 60.

As shown in FIG. 6, the image capturer 60 captures an image of the substrates 10 as the inspection target with being stored in the storage 20 included in the processor 103, for example. In other words, the controller 70 detects the placement states of the substrates 10 in the storage 20 as the states of the inspection target. Specifically, in a case in which a plurality of substrates 10 are conveyed out of the storage 20 of the processor 103, the controller 70 first captured an entire image of the plurality of substrates 10 with being stored in the storage 20. In this case, if size of the storage 20 in the Z direction is larger than a field of view of the image capturer 60, the controller 70 operates the upward/downward mover 50 and captures a plurality of images by using the image capturer 60. In this case, both the first blade support 31 and the second blade support 32 of the substrate-holding hand 30 are positioned at positions of the avoidance state, which are on the Y2-direction side.

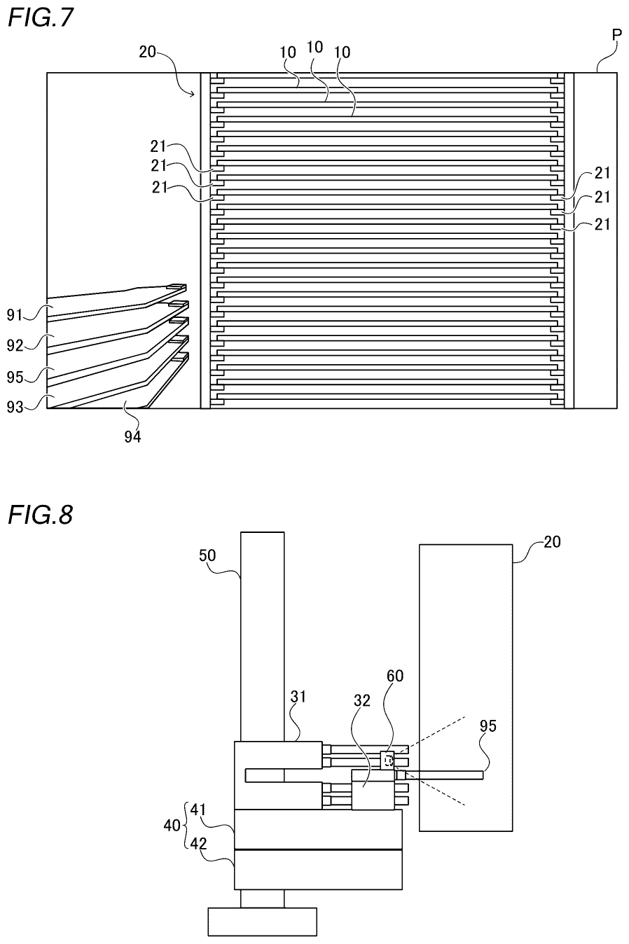

As shown in FIG. 7, the controller 70 detects, based on the captured image P of the substrates 10 captured with being stored in the storage 20, the placement states of the substrates 10 in the storage 20. For example, the controller 70 detects placement positions of the substrates 10 in the storage 20 by detecting the substrates 10 in the captured image P by using image analysis. The controller 70 applies the image analysis to the captured image P to detect shapes extending in the horizontal plane of the detected substrates 10 and deformed shapes warped with respect to the horizontal plane.

The controller 70 controls movement of the substrate-holding hand 30 based on the placement states of the substrates 10 detected based on the captured image P. Specifically, based on the detected placement states of the substrates 10, operations of the linear mover 40 and the upward/downward mover 50 are controlled so as to place the substrates 10 onto the blades 91, 92, 93, 94 and 95. In other words, the controller 70 controls movement paths of the blades 91, 92, 93, 94 and 95 based on the detected placement states of the substrates 10. Also, if detecting a deformed substrate 10 that cannot be conveyed out or in based on the detected placement state of the substrate 10, the controller 70 outputs an anomaly detection signal indicating that an anomaly occurs in conveyance of the substrate in or out to the outside through the communicator 80. The controller 70 may stop the operations of the substrate-holding hand 30 if the anomaly occurs in conveyance of the substrate in or out. Alternatively, if the anomaly occurs in conveyance of the substrate in or out, the controller 70 may continue the operations for conveyance of the substrate 10 in or out while avoiding the substrate 10 that is detected as anomalous.

As shown in FIG. 8, the image capturer 60 captures an image of the component of the processor 103 as the inspection target. The controller 70 captures a predefined number of images of a plurality of inspection targets that are previously set in maintenance that is periodically conducted at a predetermined interval, such as once a day, for example. Also, in the maintenance process, the controller 70 captures images of a plurality of inspection targets by changing a position of the image capturer 60 by operating the linear mover 40 and the upward/downward mover 50. Even in a case in which an inspection target is not positioned in a conveyance path of the substrate 10, the controller 70 controls operations of the linear mover 40 and the upward/downward mover 50 to move the second blade support 32 so as to position the image capturer 60 at a position for capturing an image of the inspection target.

For example, the image capturer 60 captures an image of the storage 20 as the inspection target with no substrate 10 being stored. In the processor 103, the storage 20 stores a plurality of substrates 10. The plurality of substrates 10 are arranged adjacent to each other in the Z direction, which is the vertical direction, with being spaced at a predetermined interval away from each other in the storage 20. The storage 20 includes a plurality of substrate placement parts 21 on which the substrates 10 are placed. The substrate placement parts 21 protrude from inner lateral surfaces of the storage 20 in the horizontal directions.

Here, the substrate placement parts 21 deteriorate with repeated use. Specifically, an anomaly such as chipping or cracking occurs in the substrate placement part 21 in some cases. Also, an anomaly of misalignment of the substrate placement part 21 occurs in some cases. In these cases, an anomaly such as misalignment of the substrate 10 placed in the storage 20 occurs.

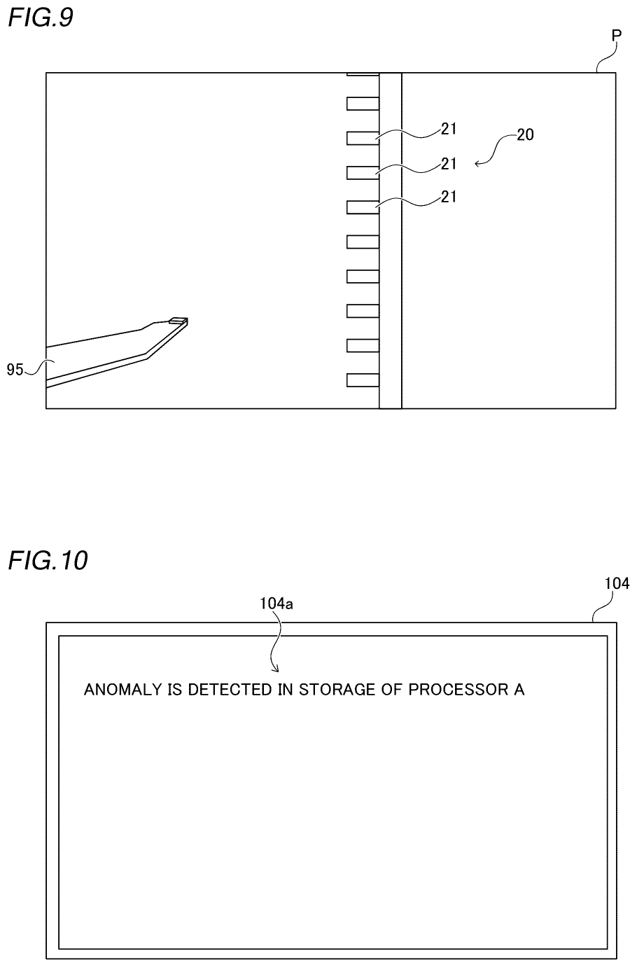

To address this, the controller 70 detects the anomaly in the substrate placement part 21 by comparing a reference image, which is previously set, with the captured image P captured by the image capturer, as shown in FIG. 9. The controller 70 detects an anomalous area in the captured image P by performing pattern matching processing using the reference image as a template, for example. The reference image is captured by the image capturer 60, and is stored in the storage device by the controller 70 every when a part of the storage 20 is replaced, or when the storage is subjected to maintenance/inspection, for example.

Here, when capturing an image of the component of the processor 103 as the inspection target, the controller 70 brings the image capturer 60 in proximity to the inspection target. In other words, the second blade support 32 is brought in proximity to the inspection target so that the image capturer 60 is brought in proximity to the inspection target. Also, at this image capture, the controller 70 does not bring the first blade support 31 in proximity to the inspection target. In other words, when capturing the image of the inspection target, the controller 70 brings the second blade support 32 on which the image capturer 60 is arranged in proximity to the inspection target while spacing the first blade support 31 further away from the inspection target than the second blade support 32. Specifically, when capturing an image of the storage 20 of the processor 103, the controller 70 brings only the second blade support 32 in proximity to the inspection target while keeping the first blade support 31 at the position of the avoidance state. As a result, while the captured image P in FIG. 8 includes the blades 91, 92, 93, 94 and 95, the captured image P in FIG. 9 does not include the blades 91, 92, 93 and 94 but includes only the blade 95. Also, when an anomaly is detected in the component of the processor 103 that is the inspection target, the controller 70 outputs an anomaly detection signal indicating that the anomaly is detected to the processor 103 through the communicator 80.

As shown in FIG. 7, the captured image P captured by the image capturer 60 includes the substrate-holding hand 30. The controller 70 detects a state of the substrate-holding hand 30 based on the captured image P. Specifically, the captured image P includes the blades 91, 92, 93, 94 and 95 of the substrate-holding hand 30. The controller 70 captures a predefined number of images of the blades 91, 92, 93, 94 and 95 of the substrate-holding hand 30 as the plurality of inspection targets that are previously set in maintenance that is periodically conducted at a predetermined interval, such as once a day, for example. Subsequently, the controller 70 detects the anomaly of misalignment, chipping or the like of any of the blades 91, 92, 93, 94 and 95 based on the captured image P. When an anomaly of the substrate-holding hand 30, which is the inspection target, is detected, the controller 70 outputs an anomaly detection signal indicating that the anomaly is detected to the processor 103 through the communicator 80.

As shown in FIG. 10, for example, in the substrate processing system 100, an anomaly detection indication 104a, which indicates that the anomaly is detected, is indicated on the display 104 of the substrate processing system 100 in response to the anomaly detection signal output from the controller 70. FIG. 10 is a view illustrating an exemplary indication when an anomaly of the storage 20 is detected in one of the plurality of processors 103. The substrate processing system 100 may also stop the operations of the substrate-conveying robot 101 and the processor 103 when the anomaly detection signal is output. Also, the controller 70 may store the captured image P in which the anomaly is detected in the storage device. In this case, a plurality of captured images P that include the captured image P in which the anomaly is detected may be stored as video.

### Processing for Controlling Substrate-Conveying Method

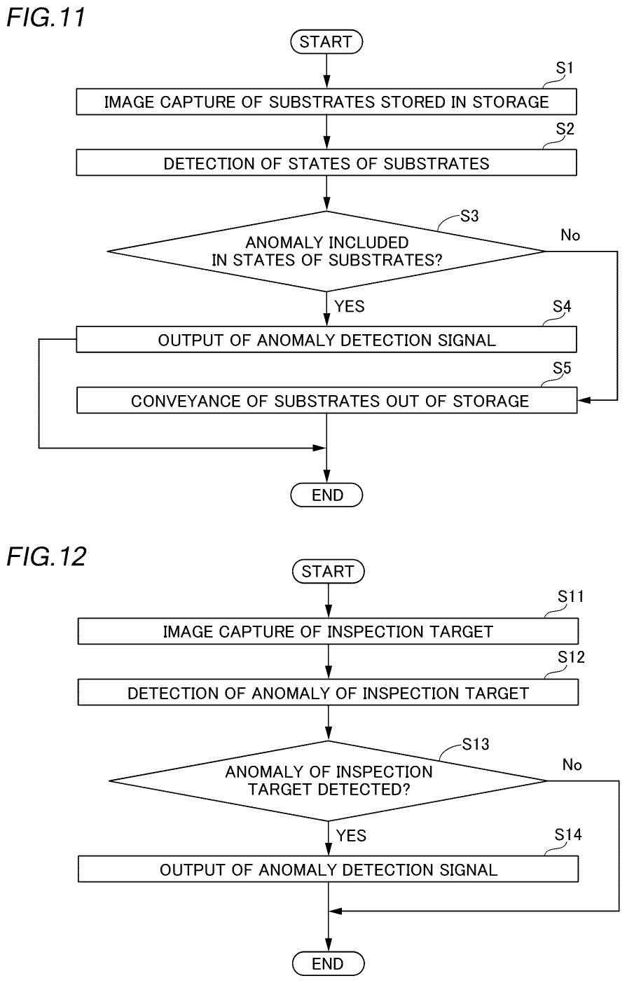

The following description will describe operations in a substrate-conveying method by the substrate-conveying robot 101 with reference to FIG. 11. In this substrate-conveying method, the states of the substrates 10 that are placed in the storage 20 is detected as the inspection target of the substrates 10. Here, the following description describes operations of conveying the substrates 10 out of the storage 20. Processing for controlling the substrate-conveying method is executed by the controller 70.

In step S1, images of the substrates 10 that are stored in the storage 20 are first captured while moving the image capturer 60 by operating the linear mover 40 and the upward/downward mover 50. In this step, a plurality of captured images P are captured by moving the image capturer 60 in the vertical direction by using the upward/downward mover 50 to capture images of all the substrates 10 that are stored in the storage 20.

Subsequently, in step S2, image analysis is performed on the captured image P to detect the states of the substrates 10 that are placed in the storage 20. Specifically, based on the captured image P, the placement position and shape of the substrate 10 in the storage 20 are detected as the placement state of the substrate 10.

Subsequently, in step S3, it is determined whether a state of any of the substrates 10 detected in the storage 20 includes an anomaly. If it is determined that the state of any of the substrates 10 includes the anomaly, the procedure goes to step S4. If it is not determined that the state of any of the substrates 10 includes any anomaly, the procedure goes to step S5.

In step S4, an anomaly detection signal indicating that the anomaly is detected is output. Also, in step S5, the substrates 10 are conveyed out of the storage 20 by controlling operations of the linear mover 40 and the upward/downward mover 50 based on the states of the substrates 10 detected in step S2. The substrates 10 that are conveyed out of the storage 20 may be conveyed into the storage enclosure 102 for storing the substrate 10, or may be conveyed into the storage 20 of a processor 103 other than a processor 103 that stored the substrates 10.

### Method for Detecting Anomaly in Inspection Target

The following description describes a method for detecting an anomaly in components of the processor 103 and the substrate-holding hand 30 with reference to FIG. 12. For example, processing for controlling the method for detecting the anomaly is periodically executed in the maintenance at a predetermined interval, such as once a day. The processing for controlling the method for detecting the anomaly in the inspection target is executed by the controller 70.

First, in step S11, an image of the inspection target is captured by the image capturer 60. For example, the inspection target is the storage 20 with no substrate 10 being placed. In a case in which the processor 103 includes a plurality of storages 20, images of the plurality of storages 20 are captured. Also, an image of the storage 20 in each of the plurality of processors 103 is captured. Also, the inspection target may be the substrate-holding hand 30. Subsequently, the captured image P is acquired by the image capture by using the image capturer 60.

Subsequently, in step S12, an anomaly of the inspection target is detected based on the captured image P. Specifically, the anomaly of the inspection target is detected by comparing a reference image, which is previously set, with the captured image P, which is acquired in step S11. Here, in a case in which a plurality of inspection targets are included, a plurality of types of reference images are previously set and stored corresponding to the plurality of inspection targets. The reference image is, for example, a captured image P that is captured every when the inspection target is subjected to maintenance or is replaced. The reference image may be a captured image P captured in previous maintenance.

Subsequently, in step S13, it is determined whether the anomaly is detected in the inspection target. If the anomaly is detected in the inspection target, the procedure goes to step S14. If the anomaly is not detected in the inspection target, the processing for controlling the method for detecting the anomaly in the inspection target ends.

In step S14, based on the detected anomaly, an anomaly detection signal indicating that the anomaly is detected is output. The anomaly detection signal is transmitted to the higher-level control apparatus 105 of the substrate processing system 100 through the communicator 80, for example. Subsequently, the anomaly detection indication 104a, which is information indicating that the anomaly is detected, is indicated on the display 104 by the control apparatus 105.

### Advantages of First Embodiment

In the first embodiment, the following advantages are obtained.

The substrate processing system 100 includes the image capturer 60 for capturing an image of the inspection target including at least one of the substrates 10, components of the storage enclosure 102 and the processor 103, and the substrate-holding hand 30; and the controller 70 for detecting a state of the inspection target based on the captured image P captured by the image capturer 60. Accordingly, since the inspection target can be captured by the image capturer 60, it is possible to capture an image of the state of the inspection target in a wider area as compared with a case in which an optical sensor is arranged in a distal end of a hand to detect storage states of substrates 10. For this reason, in a case in which the inspection target is substrates 10, states of the inspection target can be easily detected based on the captured image P captured by the image capturer. Also, the state of the inspection target can be detected based on the captured image P without light emitters and light receivers being are arranged corresponding to the inspection target by detecting the state of the inspection target based on the captured image P captured by the image capturer 60. For this reason, in a case in which the inspection target is the storage enclosure 102 and a component of the processor 103, it is possible to easily detect the state of the inspection target based on the captured image P. Also, in a case in which the inspection target is the substrate-holding hand 30 itself, it is possible to easily detect the state of the inspection target based on the captured image P. Consequently, it is possible to easily detect the state of the inspection target including at least one of the substrates 10, components of the storage enclosure 102 and the processor 103, and the substrate-holding hand 30.

The substrate processing system 100 includes the substrate-holding hand 30 including the first blade support 31 for supporting proximal ends of the blades 91, 92, 93 and 94 on which the substrates 10 are placed, and the second blade support 32 for operating independently of the first blade support 31 and for supporting a proximal end of the blade 95 on which another of the substrates 10 is placed. Also, the image capturer 60 is arranged in the second blade support 32. Accordingly, in a case in which the inspection target is the substrate 10, and at least one of the storage enclosure 102 and the component of the processor 103, since the image capturer 60 arranged in the second blade support 32 can be moved to be brought in proximity to the inspection target, an enlarged image of the inspection target can be captured in detail by the image capturer 60. For this reason, it is possible to accurately detect the state of the inspection target based on the captured image P of the inspection target captured in detail. Also, since the second blade support 32 operates independently of the first blade support 31, it is possible to prevent the first blade support 31, and the blades 91, 92, 93 and 94 supported by the first blade support 31 from being included in the captured image P. Consequently, it is possible to prevent that the first blade support 31, and the blades 91, 92, 93 and 94 included in the captured image P make detection of the state of the inspection target difficult.

The image capturer 60 moves together with the second blade support 32. Accordingly, the image capturer 60 can be moved by moving the second blade support 32. Consequently, it is possible to prevent an apparatus configuration from becoming complicated as compared with case in which a configuration for moving the image capturer 60 is provided separately from a configuration for moving the second blade support 32.

The image capturer 60 is arranged on the second blade support 32 with being spaced away from the connection part 32c between the second blade support 32 and the blade 95. Here, heat generated in the image capturer 60 causes an anomaly of an operation of the substrate-holding hand 30 in some cases. To address this, in the first embodiment, since the image capturer 60 is arranged on the second blade support 32 with being spaced away from the connection part 32c between the second blade support 32 and the blade 95, it is possible to prevent that the heat generated in the image capturer 60 causes the anomaly of the operation of the substrate-holding hand 30. Also, in a case in which the blades 91, 92, 93 and 94 supported by the first blade support 31, and the blade 95 supported by the second blade support 32 are arranged adjacent to each other in the vertical direction as in the first embodiment, the image capturer 60 can be spaced away from both each connection part 31b of the first blade support 31 and the connection part 32c of the second blade support 32 by spacing the image capturer 60 away from the connection part 32c. Accordingly, it is possible to prevent that the heat generated in the image capturer 60 causes an anomaly both in each connection part 31b of the first blade support 31 and the connection part 32c of the second blade support 32. For example, in a case in which the first blade support 31 is configured, as in the first embodiment, to support the proximal ends of the plurality of blades 91, 92, 93 and 94 and to change positions of the plurality of blades 91, 92, 93 and 94 in the vertical direction, it is possible to prevent that the heat generated in the image capturer 60 causes an anomaly of the movement of the blades 91, 92, 93 and 94 of the first blade support 31.

The image capturer 60 is arranged in a lateral part of the second blade support 32 on an outside with respect to the edge of the blade 95 as viewed in the movement direction of the blade 95 when the substrate 10 is conveyed in or out to be spaced away from the connection part 32c. Accordingly, since the image capturer 60 is arranged on the outside with respect to the edge of the blade 95, the image capturer 60 can be positioned at a position spaced sufficiently away from the connection part 32c. Consequently, it is possible to effectively prevent that the heat generated in the image capturer 60 causes the anomaly of the operation of the substrate-holding hand 30. Also, since the image capturer 60 is arranged in the lateral part on the outside with respect to the edge of the blade 95, an image of the blade 95 itself, which is supported by the second blade support 32, can be captured by the image capturer 60. Consequently, it is possible to detect an anomaly of misalignment or the like of the blade 95 based on the captured image P captured by the image capturer 60.

The image capturer 60 captures images of the inspection target including at least the substrates 10 with being stored in the storage 20 included in the processor 103 and the storage enclosure 102; and the controller 70 detects, based on the captured images P of the substrates 10 being stored in the storage 20 and the storage enclosure 102, the placement states of the substrates 10 in the storage 20 and the storage enclosure 102. Here, in a case in which optical sensors are arranged in distal ends of the blades 91, 92, 93, 94 and 95 on which the substrates 10 are placed to confirm placement states of the substrates 10, signal lines necessarily extend to the distal ends of the blades 91, 92, 93, 94 and 95 to be connected to the sensors. Since the blades 91, 92, 93, 94 and 95 on which the substrates 10 are placed typically have a relatively thin shape, work for installation of the signal lines is a burden to workers. Contrary to this, in the first embodiment, the controller 70 detects, based on the captured images P of the substrates 10 being stored in the storage 20 and the storage enclosure 102, the placement states of the substrates 10 in the storage 20 and the storage enclosure 102. Accordingly, the placement states of the substrates 10 can be detected based on the captured images P captured by the image capturer 60 provided to the second blade support 32, which supports the proximal end of the blade 95, without optical sensors arranged in the distal ends of the blades 91, 92, 93, 94 and 95. Consequently, since the signal lines are not necessarily installed to extend to the distal ends of the blades 91, 92, 93, 94 and 95, and it is possible to reduce the burden to the workers.

The substrate-holding hand 30 includes a plurality of blades 91, 92, 93 and 94, which are supported by the first blade support 31, and one blade 95, which is supported by the second blade support 32; and the image capturer 60 is arranged in the second blade support 32, which supports the proximal end of the one blade 95. Accordingly, since the image capturer 60 is arranged in the second blade support 32, which supports the proximal end of one blade 95, the second blade support 32 can be smaller than the first blade support 31, which supports the proximal ends of the plurality of blades 91, 92, 93 and 94. For this reason, since the second blade support 32 can be moved to bring the image capturer 60 into a relatively narrower area as compared with a case in which the image capturer 60 is provided to the first blade support 31, it is possible to bring the image capturer 60 in proximity to the inspection target that is arranged in the relatively narrow area to capture an image of the inspection target. Consequently, since the captured image P of the inspection target that is arranged in the relatively narrow area can acquired in detail, it is possible to accurately detect a state of the inspection target even in the case in which the target is arranged in the relatively narrow area.

The substrate processing system 100 includes the linear mover 40 for linearly moving the substrate-holding hand 30, and the linear mover 40 linearly moves the second blade support 32 independently of the first blade support 31. Accordingly, since the linear mover 40 can slidably move the substrate-holding hand 30 in a straight line, it is possible to stably move the substrate-holding hand 30 with the substrate-holding hand being supported from the lower side in the vertical direction. Also, in a case in which the substrate-holding hand 30 is linearly moved by a link mechanism including a horizontal or vertical multi-joint robot arm, its links are necessarily folded for linear movement, and as a result physical interference in a transverse direction that intersects with the movement direction is necessarily taken into account. Contrary to this, in the case in which the substrate-holding hand 30 is linearly moved by the linear mover 40, the physical interference in the transverse direction can be prevented, and as a result it is possible to linearly move the substrate-holding hand 30 to bring the substrate-holding hand into a narrower area as compared with the case of the link mechanism including the robot arm. Consequently, even when the inspection target is located in a relatively narrow position, since the image capturer 60 can be brought in proximity to the inspection target to capture the captured image P in detail, it is possible to accurately detect the state of the inspection target.

The upward/downward mover 50 for moving the linear mover 40 upward/downward is provided, and the upward/downward mover 50 moves the substrate-holding hand 30 upward/downward by moving the linear mover 40 upward/downward. Accordingly, the substrates 10 can be conveyed between storages 20 having different height positions in the vertical direction by the substrate-holding hand 30. Also, even in a case in which inspection targets are positioned at positions different from each other in the vertical direction, since the substrate-holding hand 30 can be moved upward/downward by the upward/downward mover 50, the image capturer 60 can be brought in proximity to the inspection targets at the different positions in the vertical direction to capture images of the inspection targets. Consequently, it is possible to accurately detect the states of the inspection targets even in the case in which the inspection targets are positioned at the different positions in the vertical direction.

### Second Embodiment

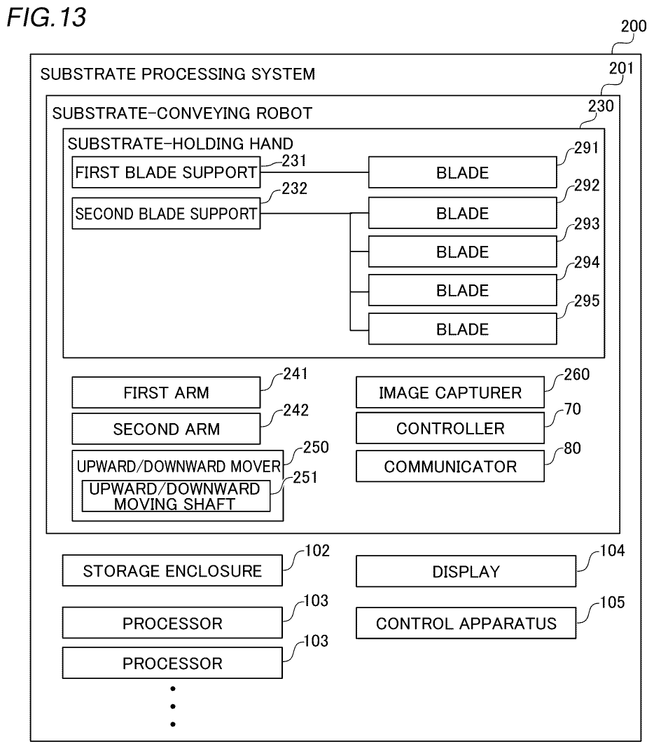

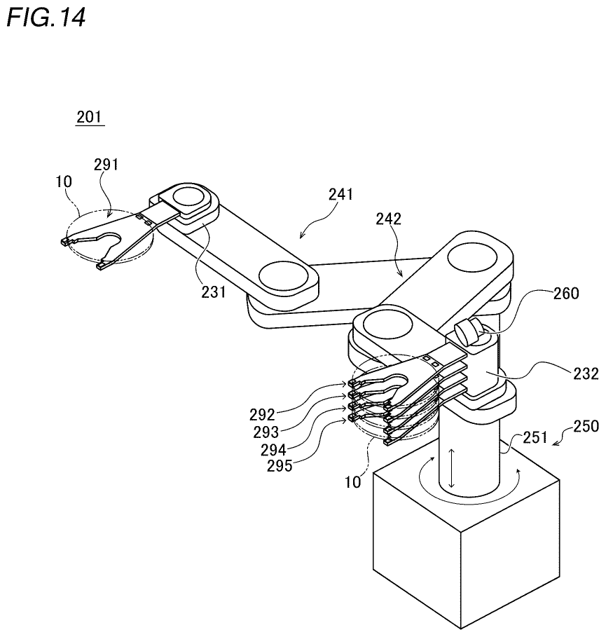

The following description describes a configuration of a substrate processing system 200 according to a second embodiment of the present disclosure with reference to FIGS. 13 and 14. An image capturer 260 is arranged on a second blade support 232 including a plurality of blades 292, 293, 294 and 295 in this second embodiment dissimilar to the aforementioned first embodiment in which the image capturer 60 is arranged in the second blade support 32 including one blade 95. The same components as those of the aforementioned first embodiment are denoted by the same reference numerals, and their description is omitted.

As shown in FIG. 13, the substrate processing system 200 according to the second embodiment includes a substrate-conveying robot 201. Also, the substrate-conveying robot 201 includes a substrate-holding hand 230, a first arm 241, a second arm 242, an upward/downward mover 250, and an image capturer 260. The substrate-holding hand 230 includes a first blade support 231 and a second blade support 232. The upward/downward mover 250 includes an upward/downward moving shaft 251. The substrate processing system 200 is an example of a semiconductor production apparatus system.

As shown in FIG. 14, the substrate-conveying robot 201 is a horizontal multi-joint robot dissimilar to the substrate-conveying robot 101 according to the first embodiment. In other words, the substrate-conveying robot 201 includes the first arm 241 and the second arm 242, which are horizontal multi-joint robot arms, instead of the linear mover 40. The first arm 241 and the second arm 242 includes two links each. The two links are connected rotatably in horizontal directions to each other. The first arm 241 and the second arm 242 are connected to the upward/downward mover 250. Each of the first arm 241 and the second arm 242 has one end connected rotatably in the horizontal directions to the upward/downward moving shaft 251 of the upward/downward mover 250. The upward/downward mover 250 moves the first arm 241 and the second arm 242 upward/downward by moving the upward/downward moving shaft 251 in the vertical direction. The first arm 241 and the second arm 242, and the upward/downward mover 250 are operated by driving forces of servomotors.

Each of the first arm 241 and the second arm 242 has another end on which the substrate-holding hand 230 is arranged. Specifically, the first blade support 231 is arranged on the another end of the first arm 241. Also, the second blade support 232 is arranged on the another end of the second arm 242. The first blade support 231 is connected rotatably in the horizontal directions to the first arm 241. Also, the second blade support 232 is configured to be able to rotate in the horizontal directions with respect to the second arm 242.

In the second embodiment, the first blade support 231 supports a proximal end of one blade 291. Also, the second blade support 232 supports proximal ends of a plurality of blades 292, 293, 294 and 295. Here, the blade 291 is an example of a first blade. The blades 292, 293, 294 and 295 are examples of a second blade.

The substrate-conveying robot 201 performs an operation of conveying one substrate 10 by using one blade 291 of the first blade support 231, and an operation of simultaneously conveying a plurality of substrates 10 by using the plurality of blades 292, 293, 294 and 295 of the second blade support 232.

In the second embodiment, the image capturer 260 is arranged in the second blade support 232, which supports the plurality of blades 292, 293, 294 and 295. Specifically, the image capturer 260 is arranged on the Z1-direction side, which is an upper side in the vertical direction, of the second blade support 232. In other words, the image capturer 260 is arranged on the upper side with respect to all the plurality of blades 292, 293, 294 and 295 in the vertical direction.

The controller 70 detects the state of the inspection target based on the captured image P captured by the image capturer 260. Processing for controlling detection of the state of the inspection target by using by the controller 70 is the same as the first embodiment.

Other configurations of the second embodiment are the same as the first embodiment above.

### Advantages of Second Embodiment

In the second embodiment, the following advantages are obtained.

The substrate-holding hand 230 includes one blade 291 supported by the first blade support 231, and the plurality of blades 292, 293, 294 and 295 supported by the second blade support 232; and the image capturer 260 is arranged in the second blade support 232, which supports the proximal ends of the plurality of blades 292, 293, 294 and 295. Accordingly, in a case in which the plurality of substrates 10 are collectively conveyed by the plurality of blades 292, 293, 294 and 295 of the second blade support 232, an image of the plurality of substrates 10 conveyed can be easily captured by the image capturer 260 arranged in the second blade support 232. Consequently, in the case in which the plurality of substrates 10 are collectively conveyed, placement states of the plurality of substrates 10 conveyed can be easily detected based on the captured image P captured by the image capturer 260. The other advantages of the second embodiment are similar to the aforementioned first embodiment.

### Third Embodiment

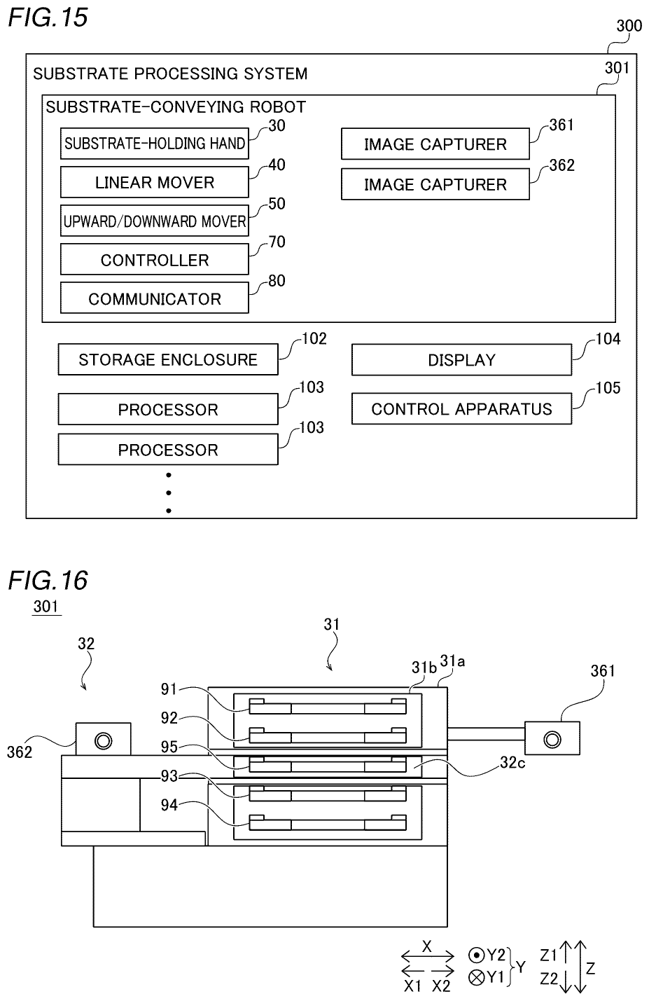

The following description describes a configuration of a substrate processing system 300 according to a third embodiment of the present disclosure with reference to FIGS. 15 and 16. Two image capturers 361 and 362 are provided in this third embodiment dissimilar to the aforementioned first embodiment in which one image capturer 60 is provided. The same components as those of the aforementioned first and second embodiments are denoted by the same reference numerals, and their description is omitted.

As shown in FIG. 15, the substrate processing system 300 according to the third embodiment includes a substrate-conveying robot 301. The substrate-conveying robot 301 includes the image capturers 361 and 362. The substrate processing system 300 is an example of a semiconductor production apparatus system. The image capturers 361 and 362 are examples of first and second image capturers, respectively.

The image capturers 361 and 362 are two-dimensional cameras similar to the image capturer 60 in the first embodiment. Also, the image capturers 361 and 362 similarly capture images of the inspection target to detect the state of the inspection target.

As shown in FIG. 16, in the third embodiment, the image capturer 361 is arranged in the first blade support 31, and the image capturer 362 is arranged in the second blade support 32. An arrangement of the image capturer 362 on the second blade support 32 is the same as the image capturer 60 in the first embodiment. In other words, in the third embodiment, in addition to the image capturer 362 arranged in the second blade support 32, the additional image capturer 361 arranged in the first blade support 31 is provided to capture an image of the inspection target.

The image capturer 361 is arranged in the casing 31a of the first blade support 31. Specifically, while the image capturer 362 is arranged on one lateral side with respect to the first blade support 31, the image capturer 361 is arranged on another lateral side, which is opposite to the one lateral side. Here, the one lateral side refers to the X1-direction side in FIG. 16, and the another lateral side refers to the X2-direction side in FIG. 16.

Also, the image capturer 362 is positioned at a position spaced away from the connection part 32c similar to the image capturer 60 in the first embodiment. Also, the image capturer 361 is arranged in the first blade support 31 to be spaced at a spacing distance substantially equal to a spacing distance of the image capturer 362 away from the connection part 32c in a direction opposite to the image capturer 362. That is, the image capturers 361 and 362 are positioned at positions spaced at the substantially equal spacing distance away from the blades 91, 92, 93, 94 and 95 in the X direction, which is a transverse direction of each of the plurality of blades 91, 92, 93, 94 and 95. Also, arrangements of the image capturers 361 and 362 in the Z-direction, which is the vertical direction, are substantially equal to each other. Accordingly, fields of view of the image capturers 361 and 362 are symmetrical to each other with respect to each of the plurality of blades 91, 92, 93, 94 and 95. Consequently, images of the plurality of blades 91, 92, 93, 94 and 95 can be captured as a wide view captured image P from both sides in a leftward/rightward direction.

The controller 70 detects the state of the inspection target based on the captured images P captured by the image capturer 361 and the image capturer 362. Processing for controlling detection of the state of the inspection target by using by the controller 70 is the same as the first embodiment.

Other configurations of the third embodiment are the same as the first embodiment above.

### Advantages of Third Embodiment

In the third embodiment, the following advantages are obtained.

The substrate processing system 300 includes the image capturer 361 arranged in the first blade support 31, and the image capturer 362 arranged in the second blade support 32 separately from the image capturer 361. Accordingly, since the image capturer 361 is arranged in the first blade support 31, and the image capturer 362 is arranged in the second blade support 32, which operates independently of the first blade support 31, the image capturer 361 and 362 can be arranged to provide different fields of view from each other. Consequently, it is possible to capture a captured image P with a wider field of view as compared with a case of a single image capturer. As a result, it is possible to easily detect the state of the inspection target located over a wider area. The other advantages of the third embodiment are similar to the aforementioned first embodiment.

### Modified Embodiments

Note that the embodiment disclosed this time must be considered as illustrative in all points and not restrictive. The scope of the present disclosure is not shown by the above description of the embodiments but by the scope of claims for patent, and all modifications (modified embodiments) within the meaning and scope equivalent to the scope of claims for patent are further included.

While the example in which the plurality of blades 91, 92, 93 and 94 are supported by the first blade support 31, and one blade 95 is supported by the second blade support 32 has been shown in the aforementioned first and third embodiments; and one blade 291 is supported by the first blade support 231, and the plurality of blades 95 are supported by the second blade support 232 has been shown in the aforementioned second embodiment, the present disclosure is not limited to these. In the present disclosure, the first blade support may support one first blade, and the second blade support may support one second blade. Alternatively, the first blade support may support a plurality of first blades, and the second blade support may support a plurality of second blades. The number of second blades supported by the second blade support on which the image capturer is arranged may be smaller than the number of first blades supported by the first blade support. Alternatively, the number of second blades may be greater than the number of first blades.

While the example in which the second blade support 32 supports the blade 95, which is positioned at a middle position in the vertical direction in the plurality of blades 91, 92, 93, 94 and 95 arranged adjacent to each other in the vertical direction has been shown in the aforementioned first and third embodiments, the present disclosure is not limited to this. In the present disclosure, the second blade support may support one blade that is positioned at the lowest position in the plurality of blades arranged adjacent to each other in the vertical direction. That is, only the one blade that is positioned at the lowest position in the plurality of blades may be operated separately from the other of the plurality of blades. Alternatively, the second blade support may support the blade that is positioned at the highest position in the vertical direction in the plurality of blades.

While the example in which the controller 70 for controlling operations of the substrate-conveying robot 101 executing detection of a state of the inspection target based on the captured image P has been shown in the aforementioned first embodiment, the present disclosure is not limited to this. In the present disclosure, the substrate-conveying robot may directly output the captured image that has been captured without executing detection of the state of the inspection target. In other words, a controller separate from the controller that controls the operations of the substrate-holding hand may execute detection of the state of the inspection target based on the captured image. For example, processing for controlling detection of the state of the inspection target may be executed in the higher-level control apparatus of the substrate processing system. Alternatively, a remote control system that is provided separately from the substrate processing system may execute detection of the state of the inspection target based on the captured image.

While the example in which the image capturer 60 is provided to move together with the second blade support 32 has been shown in the aforementioned first embodiment, the present disclosure is not limited to this. In the present disclosure, the image capturer may be arranged movably with respect to the second blade support. For example, the image capturer may be arranged to be able to change its image capture direction with respect to the second blade support.

While the example in which the image capturer 60 is arranged on the second blade support 32 with being spaced away from the connection part 32c of the second blade support 32 has been shown in the aforementioned first embodiment, the present disclosure is not limited to this. In the present disclosure, the image capturer may be arranged near the connection part of the second blade support connected to the second blade.

While the example in which the placement states of the substrates 10 in the storage 20 are detected based on the captured image P of the substrates 10 captured with being stored in the storage 20 included in the processor 103 has been shown in the aforementioned first embodiment, the present disclosure is not limited to this. In the present disclosure, the placement states of the substrates in the storage may be detected by using an optical sensor arranged on the hand instead of the image capturer.

While the example in which the image capturer 60 is arranged on the lateral side with respect to the blades 91, 92, 93, 94 and 95 has been shown in the aforementioned first embodiment, and the example in which the image capturer 260 is arranged on the upper side with respect to the blades 292, 293, 294 and 295 has been shown in the aforementioned second embodiment, the present disclosure is not limited to these. In the present disclosure, the image capturer may be arranged on the lower side with respect to the second blade in the second blade support. Also, in a case in which the substrate-holding hand is linearly moved by the linear mover, the image capturer may be arranged on the upper or lower side with respect to the second blade. Also, in a case in which the substrate-holding hand is moved by the link mechanism including a robot arm, the image capturer may be arranged on the lateral or lower side with respect to the second blade support.

While the example in which an anomaly of the storage 20 as a component of the processor 103 is detected has been shown in the aforementioned first embodiment, the present disclosure is not limited to this. In the present disclosure, a state of a consumption degree of a consumable such as an electrode or solution used for processing the substrate in the processor as a component of the semiconductor production apparatus may be detected. Also, not only the processor for processing the substrate and the storage enclosure for storing the substrate but also components of a conveyor apparatus for conveying the substrates may be the inspection target. Also, foreign matters in the processor, the storage enclosure and the conveyor apparatus may be detected as the inspection target.

While the example in which the placement states of the substrates 10 placed in the storage 20 are detected has been shown in the aforementioned first embodiment, the present disclosure is not limited to this. In the present disclosure, the placement states of the substrates held in the substrate-holding hand may be detected based on the captured image. Also, an anomaly such as chipping or deformation of the substrate held in the substrate-holding hand may be detected. Also, a state of the substrate placed in the storage enclosure may be detected.

While the example in which two blade supports of the first blade support 31 and the second blade support 32 are provided has been shown in the aforementioned first embodiment, the present disclosure is not limited to this. In the present disclosure, three or more blade supports may be provided. In this configuration, the image capturer may be arranged only in the second blade support of the three or more blade supports, or in some of the three or more blade supports including at least the second blade support.

While the example in which one image capturer 60 is arranged in the second blade support 32 of the substrate-holding hand 30 has been shown in the aforementioned first embodiment, the present disclosure is not limited to this. In the present disclosure, a plurality of image capturers may be arranged in the second blade support.

The functions of the elements disclosed herein can be performed using circuits, including general-purpose processors, dedicated processors, integrated circuits, Application Specific Integrated Circuits (ASICS), conventional circuits, and/or combinations thereof, configured or programmed to perform the disclosed functions, circuitry or processing circuits, including general-purpose processors, dedicated processors, integrated circuits, ASICs (Application Specific Integrated Circuits), conventional circuits, and/or combinations thereof. A processor is considered a processing circuit or circuits because it contains transistors and other circuitry. In the present disclosure, a circuit, unit, or means is hardware that performs an enumerated function or is hardware programmed to perform an enumerated function. The hardware may be the hardware disclosed herein or any other known hardware that is programmed or configured to perform the enumerated functions. If the hardware is a processor, which is considered a type of circuit, the circuit, means, or unit is a combination of hardware and software, and software is used to configure the hardware and/or processor.

### Modes

It is understood by those skilled in the art that the exemplary embodiments described above are specific examples of the following aspects.

### Mode Item 1

A semiconductor production apparatus system is a semiconductor production apparatus system for at least one of conveyance of substrates into and out of a semiconductor production apparatus for performing at least one of conveyance of the substrates, application of processing to the substrates and storing the substrates, the semiconductor production apparatus system including a substrate-holding hand including a first blade support for supporting a proximal end of a first blade on which one of the substrates is placed, and a second blade support for operating independently of the first blade support and for supporting a proximal end of a second blade on which another of the substrates is placed; an image capturer for capturing an image of an inspection target including at least one of the substrates, a component of the semiconductor production apparatus and the substrate-holding hand; and a controller for detecting a state of the inspection target based on the captured image captured by the image capturer, wherein the image capturer is arranged in the second blade support.

### Mode Item 2

In the semiconductor production apparatus system according to mode item 1, the image capturer is moved together with the second blade support.

### Mode Item 3

In the semiconductor production apparatus system according to mode item 1 or 2, the image capturer is arranged in the second blade support with being spaced away from a connection part between the second blade support and the second blade.

### Mode Item 4

In the semiconductor production apparatus system according to mode item 3, the image capturer is arranged in a lateral part of the second blade support on an outside with respect to an edge of the second blade as viewed in a movement direction of the second blade in the conveyance of the substrates into and out of the semiconductor production apparatus with being spaced away from the connection part.

### Mode Item 5

In the semiconductor production apparatus system according to any of mode items 1 to 4, the image capturer captures the image of the inspection target that includes at least the substrates with being stored in a storage included in the semiconductor production apparatus; and the controller detects, based on the captured image of the substrates captured with the substrates being stored in the storage, placement states of the substrates in the storage.

### Mode Item 6

In the semiconductor production apparatus system according to any of mode items 1 to 5, the substrate-holding hand includes a plurality of first blades that are supported by the first blade support as the first blade, and one second blade, which is the second blade supported by the second blade support; and the image capturer is arranged in the second blade support, which supports the proximal end of the one second blade.

### Mode Item 7

In the semiconductor production apparatus system according to any of mode items 1 to 6, a linear mover for linearly moving the substrate-holding hand is further provided; and the linear mover linearly moves the second blade support independently of the first blade support.

### Mode Item 8

In the semiconductor production apparatus system according to mode item 7, an upward/downward mover for moving the linear mover upward/downward is further provided; and the upward/downward mover moves the substrate-holding hand upward/downward by moving the linear mover upward/downward.

### Mode Item 9

In the semiconductor production apparatus system according to any of mode items 1 to 5, the substrate-holding hand includes one first blade, which is the first blade supported by the first blade support, and a plurality of second blades that are supported by the second blade support as the second blade; and the image capturer is arranged in the second blade support, which supports proximal ends of the plurality of second blades.

### Mode Item 10

In the semiconductor production apparatus system according to any of mode items 1 to 9, the image capturer includes a first image capturer arranged in the first blade support, and a second image capturer arranged in the second blade support separately from the first image capturer.

1. A semiconductor production apparatus system for at least one of conveyance of substrates into and out of a semiconductor production apparatus for performing at least one of conveyance of the substrates, application of processing to the substrates and storing the substrates, the semiconductor production apparatus system comprising:
a substrate-holding hand including a first blade support for supporting a proximal end of a first blade on which one of the substrates is placed, and a second blade support for operating independently of the first blade support and for supporting a proximal end of a second blade on which another of the substrates is placed;
an image capturer for capturing an image of an inspection target including at least one of the substrates, a component of the semiconductor production apparatus and the substrate-holding hand; and
a controller for detecting a state of the inspection target based on the captured image captured by the image capturer, wherein the image capturer is arranged in the second blade support.

2. The semiconductor production apparatus system according to claim 1, wherein the image capturer is moved together with the second blade support.

3. The semiconductor production apparatus system according to claim 1, wherein the image capturer is arranged in the second blade support with being spaced away from a connection part between the second blade support and the second blade.

4. The semiconductor production apparatus system according to claim 3, wherein the image capturer is arranged in a lateral part of the second blade support on an outside with respect to an edge of the second blade as viewed in a movement direction of the second blade in the conveyance of the substrates into and out of the semiconductor production apparatus with being spaced away from the connection part.

5. The semiconductor production apparatus system according to claim 1, wherein
the image capturer captures the image of the inspection target that includes at least the substrates with being stored in a storage included in the semiconductor production apparatus; and
the controller detects, based on the captured image of the substrates captured with the substrates being stored in the storage, placement states of the substrates in the storage.

6. The semiconductor production apparatus system according to claim 1, wherein
the substrate-holding hand includes
a plurality of first blades that are supported by the first blade support as the first blade, and
one second blade, which is the second blade supported by the second blade support; and
the image capturer is arranged in the second blade support, which supports the proximal end of the one second blade.

7. The semiconductor production apparatus system according to claim 1 further comprising a linear mover for linearly moving the substrate-holding hand, wherein
the linear mover linearly moves the second blade support independently of the first blade support.

8. The semiconductor production apparatus system according to claim 7 further comprising an upward/downward mover for moving the linear mover upward/downward, wherein
the upward/downward mover moves the substrate-holding hand upward/downward by moving the linear mover upward/downward.

9. The semiconductor production apparatus system according to claim 1, wherein
the substrate-holding hand includes
one first blade, which is the first blade supported by the first blade support, and
a plurality of second blades that are supported by the second blade support as the second blade; and
the image capturer is arranged in the second blade support, which supports proximal ends of the plurality of second blades.

10. The semiconductor production apparatus system according to claim 1, wherein
the image capturer includes
a first image capturer arranged in the first blade support, and
a second image capturer arranged in the second blade support separately from the first image capturer.
